(19) United States
(12) Patent Application Publication
(10) Pub. No.: US 2005/0115504 A1
(43) Pub. Date: Jun. 2, 2005

(54) Method and apparatus for forming thin films, method for manufacturing solar cell, and solar cell

(75) Inventors: Masashi Ueda, Yokohama-shi (JP); Tomoko Takagi, Yokohama-shi (JP); Norikazu Ito, Yokohama-shi (JP)

Correspondence Address: OSTROLENK FABER GERB & SOFFEN, 1180 AVENUE OF THE AMERICAS, NEW YORK, NY, 100368403, US

(73) Assignee: Ishikawajima-Harima Heavy Industries Co., Ltd., Tokyo (JP)

(21) Appl. No.: 10/725,905

(22) Filed: Dec. 1, 2003

(51) Int. Cl. C23C 16/00; H05H 1/24

(52) U.S. Cl. 118/723 R; 427/569; 136/256

(57) ABSTRACT

An apparatus for forming thin films forms a plurality of thin films in a single chamber by sequential formation of at least a first and a second thin film on a substrate by an antenna type plasma CVD method. This apparatus is provided with a residual material removal apparatus, which removes from the chamber residual materials resulting from the step for forming the first film and which affect the properties of the second film. A method and an apparatus for forming films and a solar cell removes residual material (including material gas) resulting in the step for forming the first film which have an effect on the properties of the second film. Since a plurality of films are deposited inside a single chamber, it is unnecessary to provide a plurality of chambers, thus enabling the apparatus and solar cell to be more compact and of reduced cost.

### BACKGROUND OF THE INVENTION

1. Field of the Invention

The present invention is a technique relating to a method for forming thin films, an apparatus for forming thin films and a solar cell, and in particular is used in a process for manufacturing a solar cell.

2. Description of Related Art

Structures consisting of deposited films are sometimes used as a solar cell. In a structure, a p-type semiconductor thin film, an intrinsic semiconductor thin film (i-type semiconductor thin film), and an n-type semiconductor thin film are deposited, in the above order or in reverse order, on a substrate formed by a transparent conductive film. Conventionally, a parallel plate in-line plasma CVD apparatus is used for formation of a semiconductor layer. In this type of plasma CVD apparatus, the substrates are held on a grounded electrode, and material gases and RF power are supplied from a counter electrode. The each electrodes has approximately the same surface area as the substrates and are arranged parallel to the substrate. Plasma is generated between the grounded electrode and the counter electrode, and the semiconductor layer is deposited. Also, a heater for heating the substrate is arranged at the rear face of the grounded electrode. In the case where a solar cell is manufactured using a parallel plate plasma CVD apparatus, a p-type semiconductor thin film layer, an i-type semiconductor thin film layer, and an n-type semiconductor thin film layer are separately deposited in a different chamber for each.

Recently, a process in which a p-type semiconductor thin film, an i-type semiconductor thin film, and an n-type semiconductor thin film are deposited in a single chamber, was proposed in Japanese Unexamined Patent Application, First Publication No. 2000-252496.

However, the properties of a solar cell manufactured by a single chamber deposition process are inferior to one manufactured by a system which deposits different kinds of thin films using separate chambers (a separate deposition system). This is due to residual materials within the chamber. For example, in the above process for manufacturing a solar cell, doping (auto-doping) the i-type semiconductor layer and the n-type semiconductor layer has been a problem. The doping (auto-doping) is due to desorption from the doping gas used for the formation of the p-type semiconductor layer. These materials mainly adsorbed at the surface of the electrode in the chamber, and the materials dope the i-type semiconductor layer and the n-type semiconductor layer at the time of formation so as to reduce the conversion efficiency of the solar cell.

When the i-type semiconductor layer is deposited after depositing the p-type semiconductor layer, in one chamber, materials containing boron caused by the B₂H₆ gas supplied at the time of depositing the player, adsorb to the counter electrode. These materials are then released at the time of depositing the i-type semiconductor layer, and taken in to inside the i-type semiconductor, and the intrinsic property is lost.

There is also a problem in that, because the temperature of the counter electrode is lower than the temperature of the substrate, the materials containing boron caused by the B₂H₆ gas easily adsorb to the electrode, and the adsorption of the aforementioned materials to the counter electrode is accelerated. Further, because the temperature of the counter electrode is low, a low density film and powder are sometimes generated on and in the vicinity of the counter electrode. A large amount of this kind of low density film and powder adsorbs, and consequently this film and powder has a great effect as a contamination source.

In order to avoid these kinds of problems, it is necessary to construct an apparatus using a different chamber for each thin film. In this case, the increase in equipment costs and the enlarged foot print has been a problem.

This invention takes this kind of situation into consideration, with the object of providing a method and apparatus for forming thin films and a method of manufacturing a solar cell, in which it is possible to obtain a thin film with the desired characteristics, when thin films are formed by deposition on a substrate, and further, to make the apparatus more compact and with reduced costs.

### SUMMARY OF THE INVENTION

A first aspect of the present invention is an apparatus for forming thin films which forms a plurality of thin films on a substrate in a single chamber by an antenna type plasma CVD method (chemical vapor deposition method) comprising a residual material removal apparatus which removes from the chamber residual materials which have an effect on the properties of the second thin film, the residual materials resulting from the step of forming the first thin film of the plurality of thin films.

The residual materials are materials which inhibit the desired semiconductor properties, for example, materials (impurities) containing Group III or Group V elements which act as a dopant. Also, an example of the first thin film is a p-type semiconductor thin film, and an example of the second thin film is an i-type semiconductor thin film.

The apparatus for removing the residual materials may have a power supply system that generates plasma by supplying power to an antenna, a gas supply system that supplies the desired kinds of raw material gases to the chamber, and an exhaust apparatus that evacuates the chamber.

A configuration of the antenna used in the antenna type plasma CVD method was exemplified in International Publication WO01/19144.

It is also possible for the chamber to have a heating apparatus or to be heated.

An example of an apparatus for forming thin films according to this invention has the following steps: the heated substrate is arranged in the chamber, the raw material gases are supplied to the chamber from the gas supply system, the interior (inside) of the chamber is maintained at a desired pressure by the exhaust apparatus while plasma is sustained, plasma is generated by the supply of power to the antenna by the power supply system, the gases are excited and decomposed, and a semiconductor thin film is formed on the substrate.

Further, this kind of construction of a gas supply system, exhaust apparatus and power supply system remove from the chamber the residual materials resulting from the doping gas contained in the raw material gas, and for example, a semiconductor thin film is formed.

Also, because the surface area of the antenna is smaller in comparison with the surface area of the substrate, and because the antenna is heated, a smaller amount of the materials resulting from the doping gas contained in the raw material gas is deposited on the antenna. As a result, thin films having the desired properties as a semiconductor film can be formed in one chamber, and a deposited thin film comprising multi-layered thin films can be formed. The aforementioned plurality of antennas are arranged to form an array antenna that generates plasma in the present invention and is exemplified in Japanese Unexamined Patent Application, First Publication No. 2003-109798.

The antenna type plasma CVD apparatus has different characteristics from that of the conventional parallel plate plasma CVD apparatus. The antenna type plasma CVD apparatus is characterized in that the surface area of the antenna is smaller than that of the substrate, and the antenna and the substrate become the same temperature. The conventional technology as disclosed in Japanese Unexamined Patent Application, First Publication No. 2000-252496 does not have these advantages. Compared to a conventional apparatus, the antenna type plasma CVD apparatus of the present invention has a smaller antenna surface area than the substrate area, and the antenna and substrate are the same temperature, so that there are fewer residual impurities in the chamber.

In this kind of antenna type plasma CVD apparatus it becomes possible to deposit a plurality of thin films in a single chamber. However, in an antenna type plasma CVD apparatus, there are residual impurities in the chamber, and because the properties of the second thin film are affected by the impurities of the first thin film when depositing a plurality of thin films, the residual materials are removed from the chamber by the apparatus for forming thin films, which is the first aspect of the present invention.

A second aspect of the present invention is a method for forming thin films wherein a plurality of thin films are formed on a substrate in a single chamber by an antenna type plasma CVD method (chemical vapor deposition method), predetermined residual materials resulting from the process of forming a first thin film are removed from the chamber after forming the first thin film, and forming a second thin film is then carried out.

According to the method of forming thin films of the present invention, raw material gases containing doping gases (impurities) are introduced into the chamber, plasma is generated by applying high frequency power to the antenna in the chamber, the raw material gas is excited and decomposed, and a semiconductor containing impurities is formed on the substrate.

Next, the residual materials resulting from the doping gas are removed from the chamber by gas replacement.

After the doping gas has been removed from the chamber, the i-type semiconductor layer is deposited.

In the formation of this i-type semiconductor thin film, Group IV hydrides (for example, SiH₄, Si₂H₆, GeH₄, CH₄), compound gases of these hydrides, and hydrogen (H₂) are supplied to the chamber, excited and decomposed in the plasma, and deposited on the substrate, forming the i-type semiconductor layer.

In the process of depositing this i-type semiconductor layer, the amount of impurities in the chamber is sufficiently small, so that autodoping is suppressed, and an i-type semiconductor thin film is formed.

Next, another semiconductor thin film containing impurities is formed, and depositions of multi-layered semiconductor thin films with different activation energies are formed in a single chamber.

The aforementioned removal of the residual materials from the chamber is not limited to the method of removal by gas replacement, and a method of evacuating the chamber and performing plasma cleaning by etching gases such as hydrogen gas is also possible.

A third aspect of the present invention is a solar cell wherein semiconductor thin films have been formed on a substrate by the above process for forming thin films.

According to this aspect of the invention, because the amount of impurities in the chamber is sufficiently small, autodoping is suppressed, and because an i-type semiconductor film is formed, a solar cell can be obtained that shows favorable current-voltage properties.

As described above, according to the apparatus for forming thin films, which is the first aspect of the present invention, impurities in the chamber are removed, with the effect that autodoping can be suppressed, and favorable solar cell properties can be obtained. Also, because a plurality of thin films are formed by deposition in a single chamber, there is no need to construct an apparatus for forming thin films which is provided with a plurality of chambers, with the effect that construction of the apparatus can be simplified, and the cost of the apparatus can be reduced.

### BRIEF DESCRIPTION OF THE DRAWINGS

FIG. 1 is a block diagram showing one of the embodiments of a structure of an apparatus for forming thin films of the present invention.

FIG. 2 is a cross-section showing an embodiment of a solar cell formed by the apparatus for forming thin films of the present invention.

FIGS. 3A through 3H are time charts showing valve opening and closing sequences for material gas lines, and VHF power supply ON/OFF sequences over time, shown as embodiments of the method for forming thin films of the present invention.

FIG. 4 is a cross-section showing another embodiment of a solar cell formed by the apparatus for forming thin films of the present invention.

FIG. 5 is a graph showing the results of a comparison of photoelectric current properties of solar cells illustrating practical examples of the apparatus for forming thin films of the present invention.

### DETAILED DESCRIPTION OF THE INVENTION

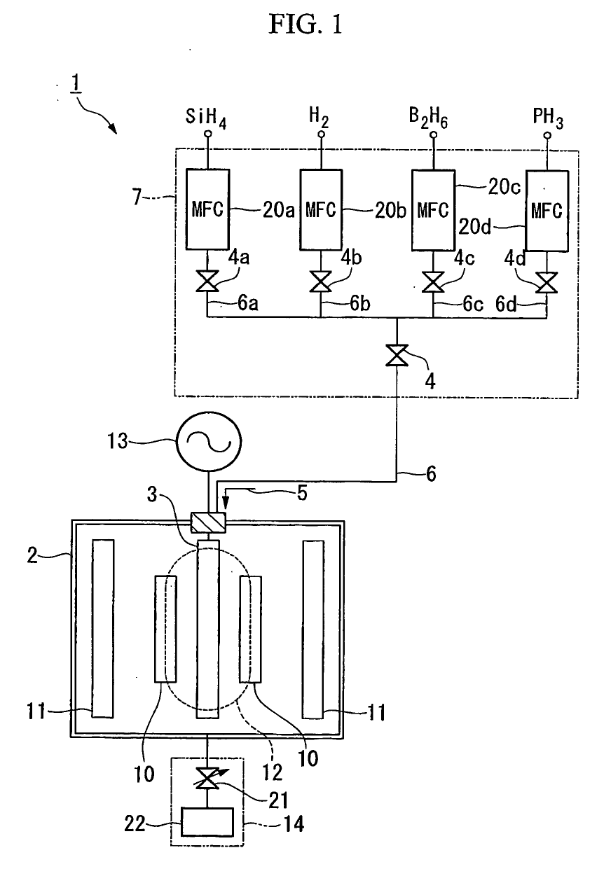

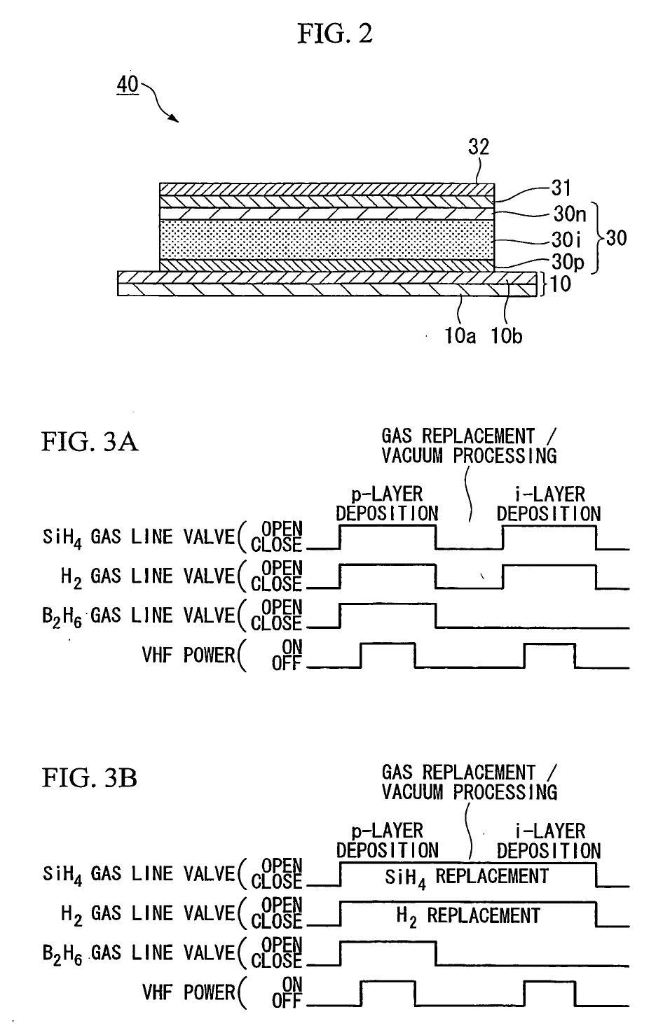

Hereunder, embodiments of the present invention will be described, with reference to the drawings. FIG. 1 is a block diagram showing one of the embodiments of a structure of an apparatus for forming thin films of the present invention. FIG. 2 is a cross-section showing an embodiment of a solar cell formed by the apparatus for forming thin films of the present invention.

As shown in FIG. 1, an apparatus for forming thin films 1 according to this embodiment is provided with a chamber 2, a U-shaped antenna 3 provided inside the chamber 2, a gas line 6 which supplies material gases 5 to the chamber 2 via a valve 4, a gas flow control apparatus 7 which controls opening and closing of the valve 4 to supply the material gases 5 to the chamber 2, a heating apparatus 11 which heats a substrate 10 arranged inside the chamber 2, a radio frequency power source 13 which generates a plasma 12 in the vicinity of the U-shaped antenna 3 in the chamber 2, and an exhaust apparatus 14 which evacuates the material gases 5 which have been supplied to the chamber 2.

In the gas flow control apparatus 7, there are provided independent gas lines 6a, 6b, 6c, and 6d for each of the SiH₄ gas, H₂ gas, B₂H₆ gas, and PH₃ gas which constitute the material gases 5, and mass flow controllers 20a, 20b, 20c, and 20d which regulate the gas flow of each of these gases.

In the exhaust apparatus 14, there is provided a pressure-regulating valve 21 which controls the pressure within the chamber 2 to a predetermined pressure, and a vacuum pump 22 which evacuates the material gases 5 from inside the chamber 2.

Also, as shown in FIG. 2, the substrate 10 is pre-formed with a transparent electrode 10b on a transparent substrate 10a made of glass. This transparent electrode 10b is formed from SnO₂, and it may also be formed by a transparent conductive oxide film such as ITO.

Next, the forming of a thin film by the step of the above apparatus for forming thin films 1, particularly in relation to the manufacture of solar cells, will be described. When the apparatus for forming thin films is started up, the chamber 2 is evacuated by the exhaust apparatus 14, and the substrate temperature is raised by the heating apparatus. When the pressure within the chamber 2 and the temperature of the heating apparatus 11 have reached a predetermined value, the apparatus for forming thin films 1 reaches a stand-by state.

In this state, the substrate 10, which has been heated by a heating apparatus (not shown in figure) in a load-lock chamber (not shown in the figures), is transferred by a transfer system (not shown in the figure) into the chamber 2 of the apparatus for forming thin films 1, and arranged facing the U-shaped antenna 3, and the temperature of the substrate 10 is maintained at a predetermined temperature by the heating apparatus 11. Next, the material gases 5 are supplied into the chamber 2 by the gas flow control apparatus 7, and the pressure within the chamber 2 is adjusted by the pressure-regulating valve 21 of the exhaust apparatus 14. Moreover, high frequency power (VHF) is supplied to the U-shaped antenna 3 by the radio frequency generator 13, and the plasma 12 of the material gases 5 is generated.

The material gases 5 are excited and decomposed by the plasma 12, and a semiconductor layer 30 is formed on the substrate 10. Because the temperature of the substrate 10 is maintained between 100° C. and 350° C. by the heating apparatus 11, the semiconductor layer 30 as shown in FIG. 2 is formed as a dense film.

The gas flow control apparatus 7 controls the valves 4a, 4b, 4c, and 4d and the mass flow controllers 20a, 20b, 20c, and 20d to mix the SiH₄ gas, the H₂ gas, the B₂H₆ gas, and the PH₃ gas in predetermined proportions and supply these to the chamber 2, so that a p-type semiconductor layer 30p, an i-type semiconductor layer 30i, and an n-type semiconductor layer 30n, constituting the semiconductor layer 30, are formed consecutively on the substrate 10.

In this kind of process for forming the semiconductor layer 30, gas that is no longer required is evacuated from the chamber 2, supplied to a removal apparatus (not shown in the figure) through the exhaust apparatus 14, and residual gas pressure is reduced.

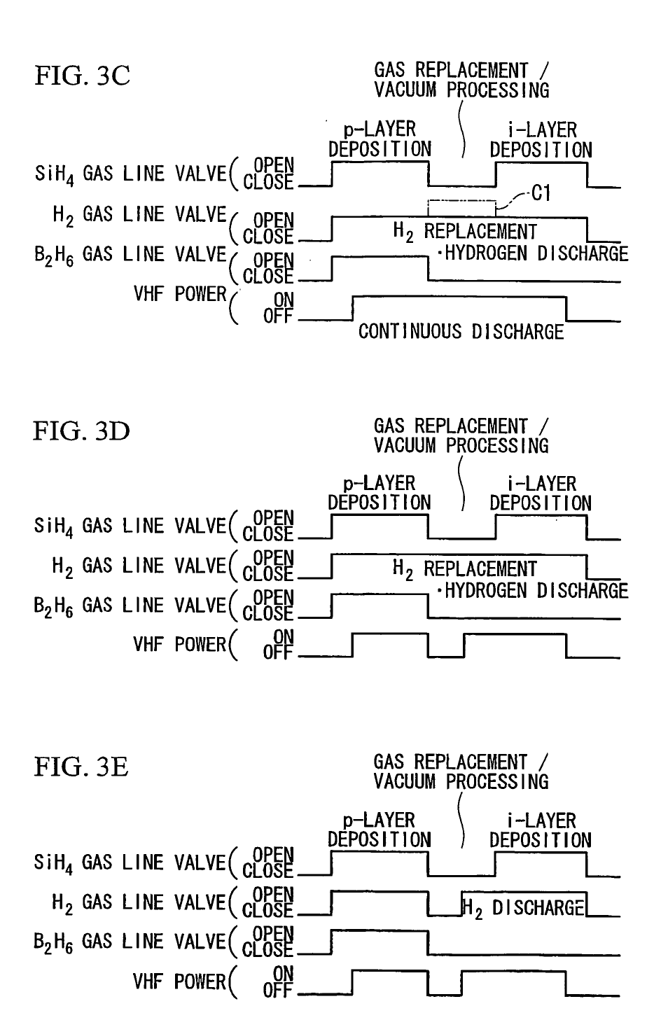

Next, a method of depositing the p-type semiconductor layer 30p and the i-type semiconductor layer 30i in the above process for forming thin films will be described in detail, with reference to the time charts shown in FIG. 3A through FIG. 3D, and FIG. 3E through FIG. 3G. The time chart shown in FIG. 3A through FIG. 3G shows the valve opening and closing sequences of the material gas lines, and the VHF power supply ON/OFF sequences over time. These are shown as embodiments of the method of forming thin films of the present invention. The OPEN/CLOSE sequence of the SiH₄ gas valve in this time chart shows the supply or non-supply of the SiH₄ gas to the chamber 2 by the step of the OPEN/CLOSE of this valve. This OPEN/CLOSE sequence is the same as for the other gases. Also, the ON/OFF sequence of the VHF power supply shows the generation or non-generation of the plasma 12 by the ON/OFF sequence of the power switch of the radio frequency generator 13.

Thin Film Forming Method 1

This Thin Film Forming Method 1 will be described following the time chart shown in FIG. 3A. Firstly, in step 1, the p-type semiconductor layer 30p is formed by supplying SiH₄, H₂, and B₂H₆ into the chamber 2, and generating the plasma 12 under these conditions. After a predetermined period of time, generation of the plasma 12 is stopped, thus stopping the formation of the p-type semiconductor layer 30p. In step 2, after simultaneously stopping the supply of SiH₄, H₂, and B₂H₆, the chamber 2 is evacuated, and any residual gas is discharged by fully opening the pressure-regulating valve 21. In step 3, the i-type semiconductor layer 30i is formed on the p-type semiconductor layer 30p by supplying SiH₄ and H₂ into the chamber 2 and generating the plasma 12 under these conditions. After a predetermined period of time, generation of the plasma 12 is stopped, thus stopping the formation of the i-type semiconductor layer 30i.

In this kind of thin film forming method 1, because any residual gases are discharged from the chamber by evacuation after the formation of the p-type semiconductor layer 30p, autodoping by the B₂H₆ gas and materials resulting from residual B₂H₆ gas in the chamber 2 is suppressed in the process for forming the i-type semiconductor layer 30i.

Thin Film Forming Method 2

This Thin Film Forming Method 2 will be described following the time chart in FIG. 3B.

Firstly, in step 1, the p-type semiconductor layer 30p is formed by supplying SiH₄, H₂ and B₂H₆ into the chamber 2, and generating the plasma 12 under these conditions. After a predetermined period of time, generation of the plasma 12 is stopped, thus stopping the formation of the p-type semiconductor layer 30p.

In step 2, only the supply of B₂H₆ is stopped, and SiH₄ and H₂ are supplied continuously to the chamber 2. As a result, B₂H₆ gas and materials attributable to the B₂H₆ gas are discharged from the chamber so that they do not affect the deposition of the i-type semiconductor.

In step 3, the i-type semiconductor layer 30i is formed on the p-type semiconductor layer 30p, by generation of the plasma 12 while SiH₄ and H₂ are being continuously supplied to the chamber 2. After a predetermined period of time, generation of the plasma 12 is stopped, thus stopping the formation of the i-type semiconductor layer 30i.

In this kind of thin film forming method 2, B₂H₆ is discharged after the formation of the p-type semiconductor layer 30p, and autodoping by the B₂H₆ gas and materials attributable to residual B₂H₆ gas in the chamber 2 is suppressed in the process for forming the i-type semiconductor layer 30i.

Thin Film Forming Method 3

This Thin Film Forming Method 3 will be described following the time chart in FIG. 3C.

Firstly, in step 1, the p-type semiconductor layer 30p is formed by supplying SiH₄, H₂, and B₂H₆ into the chamber 2, and generating the plasma 12 under these conditions. After a predetermined period of time, the supply of SiH₄ and B₂H₆ is simultaneously stopped, thus stopping the formation of the p-type semiconductor layer 30p.

In step 2, the B₂H₆ is discharged by a continuous supply of H₂ and generation of the plasma 12. Moreover, the materials resulting from residual B₂H₆ gas in the chamber 2 are discharged by the step of plasma cleaning by the plasma 12. In this case, the amount of H₂ supplied is increased, and the speed of replacement by the H₂ increases as shown by C1 in the time chart in FIG. 3C. Then the removal of materials resulting from the B₂H₆ gas by the B₂H₆ discharge and by the plasma cleaning using hydrogen plasma is accelerated.

In step 3, with the continuous supply of H₂ and generation of the plasma 12, SiH₄ is supplied into the chamber 2, and the i-type semiconductor layer 30i is formed on the p-type semiconductor layer 30p. After a predetermined period of time, generation of the plasma 12 is stopped, thus stopping the formation of the i-type semiconductor layer 30i.

In this kind of thin film forming method 3, after the formation of the p-type semiconductor layer 30p, the H₂ removes the B₂H₆ by carrying away and replacing (purging) any B₂H₆ inside the chamber 2. Moreover, the materials attributable to residual B₂H₆ in the chamber 2 are removed by the step of plasma cleaning by the H₂ plasma. Therefore, autodoping by the B₂H₆ gas and materials resulting from residual B₂H₆ gas in the chamber 2 is suppressed in the process for forming the i-type semiconductor layer 30i.

Thin Film Forming Method 4

This Thin Film Forming Method 4 will be described following the time chart in FIG. 3D.

Firstly, in step 1, the p-type semiconductor layer 30p is formed by supplying SiH₄, H₂, and B₂H₆ into the chamber 2, and generating the plasma 12 under these conditions. After a predetermined period of time, the supply of SiH₄ and B₂H₆ and generation of the plasma 12 are stopped, thus stopping the formation of the p-type semiconductor layer 30p.

In step 2, B₂H₆ is discharged by generating plasma 12 in a state where H₂ is continuously supplied, and B₂H₆ in the chamber 2 is removed. Also, materials resulting from residual B₂H₆ gas in the chamber 2 are removed by the step of plasma cleaning by the hydrogen plasma 12.

In step 3, SiH₄ is supplied into the chamber 2 while H₂ is supplied continuously and the plasma 12 is generated, and the i-type semiconductor layer 30i is formed on the p-type semiconductor layer 30p. After a predetermined period of time, generation of the plasma 12 is stopped, thus stopping the formation of the i-type semiconductor layer 30i.

In this kind of thin film forming method 4, after the formation of the p-type semiconductor layer 30p, the B₂H₆ is removed by the H₂ purge step. Moreover, the materials resulting from residual B₂H₆ in the chamber 2 are removed by the step of plasma cleaning by the H₂ plasma. Therefore, autodoping by the B₂H₆ gas and materials resulting from residual B₂H₆ gas in the chamber 2 is suppressed in the process for forming the i-type semiconductor layer 30i.

Thin Film Forming Method 5

This Thin Film Forming Method 5 will be described following the time chart in FIG. 3E.

Firstly, in step 1, the p-type semiconductor layer 30p is formed by supplying SiH₄, H₂, and B₂H₆ into the chamber 2, and generating the plasma 12 under these conditions. After a predetermined period of time, generation of the plasma 12 is stopped, thus stopping the formation of the p-type semiconductor layer 30p.

In step 2, after simultaneously stopping the supply of SiH₄, H₂, and B₂H₆, they are discharged by fully opening the pressure-regulating valve 21. After a predetermined period of time, materials resulting from residual B₂H₆ gas in the chamber 2 are removed by supplying H₂ into the chamber 2 and generating the plasma 12, and plasma cleaning takes place.

In step 3, SiH₄ is supplied into the chamber 2 while H₂ is supplied continuously and the plasma 12 is generated, and the i-type semiconductor layer 30i is formed on the p-type semiconductor layer 30p. After a predetermined period of time, generation of the plasma 12 is stopped, thus stopping the formation of the i-type semiconductor layer 30i.

In this kind of thin film forming method 5, after formation of the p-type semiconductor layer 30p, residual gases are removed by evacuation. Moreover, the materials resulting from residual B₂H₆ in the chamber 2 are removed by the step of plasma cleaning by the H₂ plasma. Therefore, autodoping by the B₂H₆ gas and materials resulting from residual B₂H₆ gas in the chamber 2 is suppressed in the process for forming the i-type semiconductor layer 30i.

Thin Film Forming Method 6

This Thin Film Forming Method 6 will be described following the time chart in FIG. 3F.

Firstly, in step 1, the p-type semiconductor layer 30p is formed by supplying SiH₄, H₂, and B₂H₆ into the chamber 2, and generating the plasma 12 under these conditions. After a predetermined period of time, generation of the plasma 12 is stopped, thus stopping the formation of the p-type semiconductor layer 30p.

In step 2, after simultaneously stopping the supply of SiH₄, H₂, and B₂H₆, they are evacuated by fully opening the pressure-regulating valve 21, and residual gases in the chamber 2 are removed. After a predetermined period of time, by supplying H₂ into the chamber 2 and generating the plasma 12, plasma cleaning takes place. After a predetermined period of time, residual gases in the chamber 2 are removed by the aforementioned evacuation.

In step 3, SiH₄ and H₂ are supplied into the chamber 2, and by generating the plasma 12 under these conditions, the i-type semiconductor layer 30i is formed on the p-type semiconductor layer 30p. After a predetermined period of time, generation of the plasma 12 stops, thus stopping the formation of the i-type semiconductor layer 30i.

In this kind of thin film forming method 6, after formation of the p-type semiconductor layer 30p, the residual gases are removed by caring out evacuation twice. Moreover, the materials resulting from residual B₂H₆ in the chamber 2 are removed by the step of plasma cleaning by the H₂ plasma. Therefore, autodoping by the B₂H₆ gas and materials resulting from residual B₂H₆ gas in the chamber 2 is suppressed in the process for forming the i-type semiconductor layer 30i.

Thin Film Forming Method 7

This Thin Film Forming Method 7 will be described following the time chart in FIG. 3G.

Firstly, in step 1, the p-type semiconductor layer 30p is formed by supplying SiH₄, H₂, and B₂H₆ into the chamber 2, and generating the plasma 12 under these conditions. After a predetermined period of time, the supply of B₂H₆ is stopped, thus stopping the formation of the p-type semiconductor layer 30p.

In step 2, SiH₄, and H₂ are continuously supplied into the chamber 2. Moreover, by stopping the supply of B₂H₆ while the plasma 12 is continuously generated, the i-type semiconductor layer 30i is formed while the concentration of B₂H₆ gas in the chamber 2 is decreasing. After a predetermined period of time, generation of the plasma 12 is stopped, thus stopping the formation of the i-type semiconductor layer 30i.

In this kind of Thin Film Forming Method 7, B₂H₆ is removed by the step of an H₂ purge after the formation of the p-type semiconductor layer 30p. Therefore autodoping by the B₂H₆ gas and materials resulting from residual B₂H₆ gas in the chamber 2 is suppressed in the process for forming the i-type semiconductor layer 30i.

In this way, the i-type semiconductor layer 30i is formed after the formation of the p-type semiconductor layer 30p, and next, the n-type semiconductor layer 30n is formed in the chamber 2. For the n-type semiconductor layer 30n, the SiH₄, H₂, and PH₃ supplied to the chamber 2 by the gas flow control apparatus 7 are decomposed by the plasma 12, and the n-type semiconductor layer 30n is formed on the substrate 10.

In this way the semiconductor layer 30 is formed by the p-type semiconductor layer 30p, the i-type semiconductor layer 30i, and the n-type semiconductor layer 30n being consecutively deposited. After that, as shown in FIG. 2, a solar cell 40 is manufactured by depositing a conductive film 31 made from ZnO and a metal film 32 made from Ag on the n-type semiconductor layer 30n.

As described above, in the apparatus for forming thin films 1, because the B₂H₆ gas and the materials resulting from residual B₂H₆ gas in the chamber 2 are removed, autodoping by the B₂H₆ gas and materials resulting from residual B₂H₆ gas in the chamber 2 can be suppressed when the i-type semiconductor layer 30i is formed.

Also, because this autodoping can be suppressed, the solar cell 40 formed by the above thin film forming methods is able to realize excellent photoelectric current properties. Further, because the p-type semiconductor layer 30p, the i-type semiconductor layer 30i and the n-type semiconductor layer 30n are formed consecutively in a single chamber 2, there is no need to provide a plurality of deposition chambers, enabling a reduction in the cost of equipment.

In Thin Film Forming Methods 1 through 7 of the present embodiments, processes were performed involving any one of: (1) evacuation of the chamber 2, (2) gas replacement by either H₂ or SiH₄, or both of these, and (3) plasma cleaning using an etching gas such as hydrogen gas or the like. However, other methods using a combination of these processes are also possible. For example, the method shown in FIG. 3H is also a method of the present invention because it is a combination of thin film forming methods 1 and 2. In whichever processing method, autodoping can be suppressed by removing the B₂H₆ gas and materials resulting from B₂H₆ gas in the chamber 2.

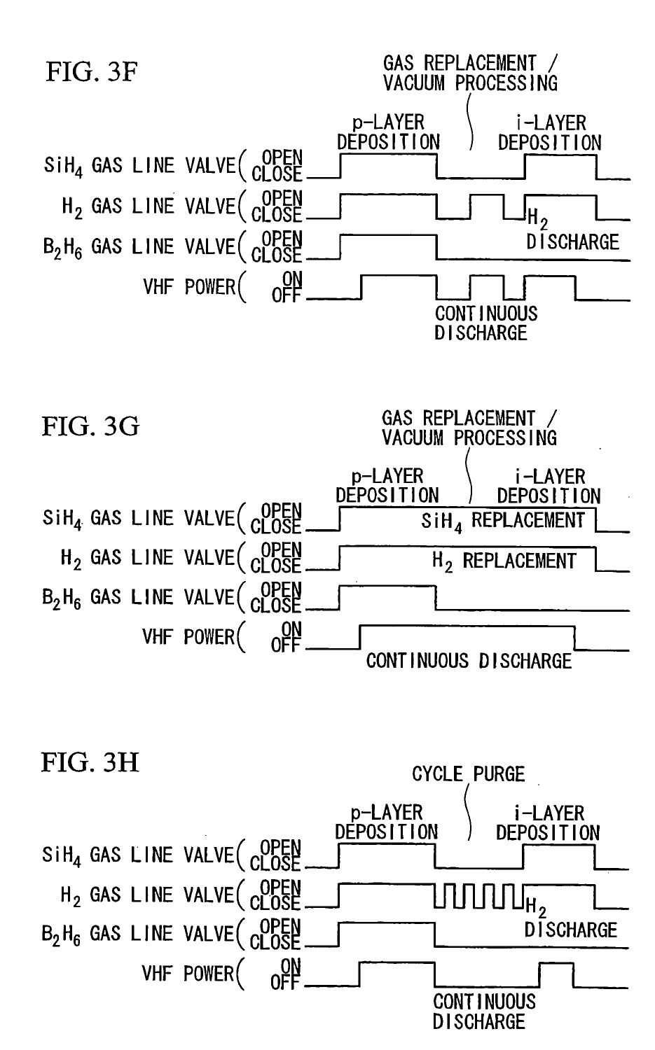

FIG. 4 is a cross-section showing a different embodiment of a solar cell formed by the apparatus for forming thin films according to the present invention. The parts in FIG. 4 which are the same as those in FIG. 1 and FIG. 2 are denoted by the same reference symbols, and a description is omitted.

The solar cell 50 shown in FIG. 4 comprises a p-type semiconductor layer 30p, an amorphous i-type semiconductor layer 51i, an n-type semiconductor layer 30n, a p-type semiconductor layer 30p, a crystalline i-type semiconductor layer 52i, an n-type semiconductor layer 30n, a conductive film 31 made from ZnO, and a metal film 32 made from Ag.

This solar cell 50 is manufactured inside the chamber 2 of the apparatus for forming thin films 1. In the manufacture of the solar cell 50, autodoping is suppressed by removing the B₂H₆ gas and materials resulting from B₂H₆ gas in the chamber 2 as mentioned before.

In the above embodiments, a method of forming a semiconductor layer 30 has been described. However the present invention is not limited to a method and apparatus for forming thin films for use in solar cells, and is also effective in the formation of apparatus having a multi-layered deposition structure such as a thin film transistor (TFT) and the like in terms of prevention of cross-contamination such as auto-doping.

Next, the present invention will be specifically illustrated by practical examples and comparative examples.

The substrate 10 on which SnO₂ has been deposited is transferred to the chamber 2 in the apparatus for forming thin films 1 of the present invention, and the substrate 10 is maintained at a target temperature by the heating apparatus 11. Next, the material gases 5 of SiH₄, H₂, B₂H₆, and PH₃, depending on the semiconductor layer being deposited, are supplied to the chamber 2, and the pressure within the chamber 2 is adjusted by the pressure-regulating valve 21 of the exhaust apparatus 14.

Moreover, the radio frequency generator 13 supplies high frequency power (VHF) to the U-shaped antenna 3 to generate the plasma 12 of the material gases 5, and form the semiconductor layer 30 which is made from the p-type semiconductor layer 30p, the i-type semiconductor layer 30i, and the n-type semiconductor layer 30n.

In the process for forming this semiconductor layer 30, between the process for forming the p-type semiconductor layer and the process for forming the i-type semiconductor layer, processes are performed involving any one of: (1) evacuation of the chamber 2, (2) gas replacement by either H₂ or SiH₄, or both of these, and (3) plasma cleaning using an etching gas such as hydrogen gas, to thereby remove the B₂H₆ gas and materials resulting from B₂H₆ gas in the chamber 2.

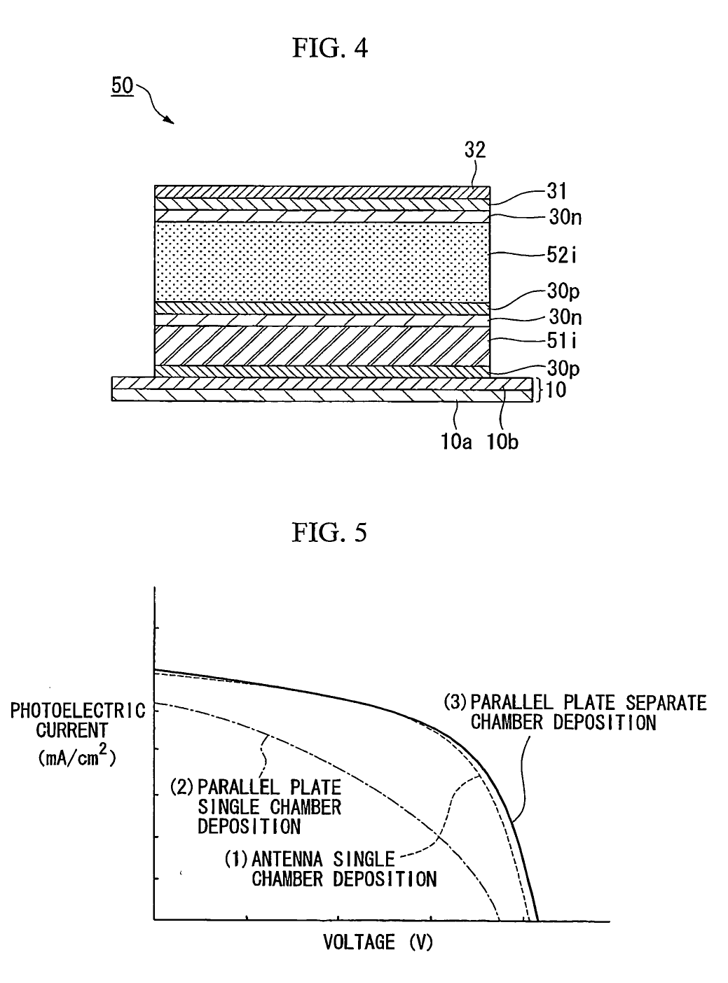

FIG. 5 is a graph showing the photoelectric current properties of a solar cell, and showing the results of a comparison of the photoelectric current properties of solar cells formed by the following three methods.
(1) A method of forming a solar cell by antenna type plasma CVD in a single chamber (antenna type single chamber deposition).
(2) A method of forming a solar cell by parallel plate plasma CVD in a single chamber (parallel plate single chamber deposition).
(3) A method of forming a solar cell by parallel plate plasma CVD, changing the chamber for each semiconductor layer (parallel plate separate chamber deposition).

It was confirmed that the current-voltage characteristics of a solar cell formed by antenna type single chamber deposition according to the present invention were more favorable than those of a solar cell formed by parallel plate single chamber deposition. Furthermore, the current-voltage characteristics of a solar cell formed by antenna type single chamber deposition according to the present invention were approximately the same as those of a solar cell formed by parallel plate separate chamber deposition.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

1. An apparatus for forming thin films, comprising:
a chamber for sequential formation of at least a first thin film and a second thin film on a substrate by an antenna type plasma CVD method; and
a residual material removal apparatus which removes from the chamber residual materials which have an effect on the properties of the second thin film, the residual materials resulting from a step of forming the first thin film of the plurality of thin films.

2. A method for forming thin films, comprising the steps of:
forming a plurality of thin films by the sequential formation of at least a first thin film and a second thin film on a substrate in one chamber by an antenna type plasma CVD method,
removing residual materials after a step for forming the first thin film, and
forming the second thin film after the step for removing residual materials.

3. A method for forming thin films according to claim 2, wherein
the second thin film is a semiconductor film, and
the residual materials are materials which inhibit the semiconductor properties of the second thin film.

4. A method for forming thin films according to claim 2, wherein the step of removing the residual materials inside a chamber is performed, and the step of removing the residual materials includes plasma cleaning which generates plasma in the vicinity of an array antenna.

5. A method for forming thin films according to claim 4, wherein the plasma cleaning is performed by hydrogen plasma.

6. A method for forming thin films according to claim 2, wherein the step of removing the residual materials inside a chamber includes a step of gas replacement.

7. A method for forming thin films according to claim 2, wherein the step of removing the residual materials inside a chamber includes a step of evacuation of the chamber.

8. A method for manufacturing a solar cell comprising the step of forming semiconductor thin films on a substrate by the method of forming thin films according to claim 2.

9. A solar cell manufactured by the method for manufacturing a solar cell according to claim 8.
